(19) United States
(12) Patent Application Publication
(10) Pub. No.: US 2004/0253802 A1
(43) Pub. Date: Dec. 16, 2004

(54) Method of plating electrode formation

(76) Inventor: Takaharu Yamano, Nagano-shi (JP)

Correspondence Address: LADAS & PARRY LLP, 224 SOUTH MICHIGAN AVENUE, SUITE 1200, CHICAGO, IL, 60604, US

(21) Appl. No.: 10/858,548

(22) Filed: Jun. 1, 2004

(30) Foreign Application Priority Data
Jun. 11, 2003 (JP) NO.2003-166818

(51) Int. Cl. H01L 21/44

(52) U.S. Cl. 438/612

(57) ABSTRACT

A method of forming a plating electrode is disclosed that provides an increased degree of freedom in shape and position of the plating electrode. A light shielding layer is formed on a negative resist layer in a ring shape corresponding to the edge of the negative resist layer. Then, with a projection lithography stepper, and only one type of reticle pattern, specified regions of the negative resist layer are exposed one by one. Subsequently, the portion of the negative resist layer below the light shielding layer is removed by a developing treatment, and the portion of a conductive metal layer previously covered by the removed negative resist layer 120 is exposed. This exposed portion of the conductive metal is used as the plating electrode.

### BACKGROUND OF THE INVENTION

1. Field of the Invention

The present invention relates to a method of forming a plating electrode used for forming conductive posts or others on a semiconductor wafer by plating.

2. Description of the Related Art

In a semiconductor product, for example, a Super Chip-Size Package (Super CSP) product, copper or other conductive posts are formed by plating on a surface of a semiconductor chip cut out from a semiconductor wafer. Also, in the process of forming a semiconductor product having bumps, solder bumps are formed by plating on a surface of a semiconductor wafer. Prior to the plating treatment, plating electrodes are formed on the semiconductor wafer.

For example, Japanese Laid Open Patent Application No. 2003-031768 discloses background art of this technology.

FIG. 1 through FIG. 6 illustrate the process of forming plating electrodes in the related art.

FIG. 1 is a top view of a semiconductor substrate.

FIG. 2 is a cross-sectional view of the semiconductor substrate in FIG. 1 along the line AA′.

In step 1, as illustrated in FIG. 1 and FIG. 2, a conductive metal layer 610 is formed on a semiconductor wafer 600 by sputtering.

FIG. 3 is a top view of the semiconductor substrate for explaining the subsequent process of forming plating electrodes continued from FIG. 1.

FIG. 4 is a cross-sectional view of the semiconductor substrate in FIG. 3 along the line AA′.

In step 2, as illustrated in FIG. 3 and FIG. 4, a negative resist layer 620 is formed on the conductive metal layer 610. Further, a protection film (not illustrated) is disposed on the negative resist layer 620 to protect the negative resist layer 620 after the step 2 and before a subsequent step 3 (described below).

FIG. 5 is a top view of the semiconductor substrate for explaining the subsequent process of forming plating electrodes continued from FIG. 3.

In step 3 as illustrated in FIG. 5, a reticle pattern (not illustrated) is disposed at a specified position above the negative resist layer 620, and a projection lithography stepper (not illustrated) emits violet rays onto the negative resist layer 620 through the reticle pattern to exposes the negative resist layer 620. After that, the protection film on the negative resist layer 620 is removed.

In the grid area shown in FIG. 5, each cell 700 indicates an area exposed by the projection lithography stepper one time (referred to as unit exposure area below). The projection lithography stepper exposes the cells 700, specifically, 700-1, 700-2, and so on, one by one. In this process, the projection lithography stepper is controlled so as not to expose areas of the negative resist layer 620 where plating electrodes are to be formed, and for this purpose, a number of types of reticle patterns are used in the exposure process.

Specifically, in FIG. 5, when exposing the cell 700-1, in order not to expose the area of the negative resist layer 620 where a conductive post is to be formed, a reticle pattern for the conductive post region is used in the region where the conductive post is to be formed. On the other hand, when exposing the cell 700-2, in order not to expose the area of the negative resist layer 620 where a plating electrode is to be formed, a reticle pattern for the plating electrode region is used in the region where the plating electrode is to be formed.

FIG. 6 is a top view of the semiconductor substrate for explaining the subsequent process of forming plating electrodes continued from FIG. 5.

In step 4, the plating electrode regions of the negative resist layer 620, which are not exposed in step 3, are removed, and the exposed areas of the conductive metal layer 610 are used as plating electrodes 650.

In the following plating treatment, corresponding contact pins are arranged in contact with these plating electrodes 650 to establish electrical connection, and thereby, conductive posts are formed on the conductive metal layer 610.

In practical use, it is required that the plating electrodes be formed at various positions on the semiconductor wafer and in various shapes according to the shapes and sizes of the semiconductor products to be fabricated after being cut out from the semiconductor wafer. According to the method of forming plating electrodes of the related art, however, a number of types of reticle patterns have to be prepared according to the shapes and sizes of the plating electrodes. In other words, the shapes and sizes of the plating electrodes depend on the reticle patterns. Due to this, there is a lesser degree of freedom for shapes and positions of the plating electrodes.

### SUMMARY OF THE INVENTION

Accordingly, it is a general object of the present invention to solve one or more problems of the related art.

A more specific object of the present invention is to provide a method of forming a plating electrode that provides a greater degree of freedom in shape and position of the plating electrode.

The present invention provides a method of forming a plating electrode, comprising the steps of forming a conductive layer on a semiconductor wafer; forming a resist layer on the conductive metal layer; forming a light shielding layer on the resist layer to prevent the resist layer from being exposed; exposing predetermined regions of the resist layer one by one; removing the light shielding layer; and removing a portion of the resist layer previously covered by the light shielding layer to expose a portion of the conductive metal layer for the plating electrode.

In an embodiment, in the step of forming the light shielding layer, the light shielding layer may be formed by printing a light shielding material on the resist layer.

In an embodiment, in the step of forming the light shielding layer, the light shielding layer may be formed to cover a peripheral region of the resist layer. In addition, the light shielding layer may in a ring shape.

In an embodiment, in the step of forming the light shielding layer, the light shielding layer may include a plurality of light shielding members. In addition, each of the light shielding members may be arranged to face another one of the light shielding members.

In an embodiment, the step of forming the light shielding layer includes the steps of forming the light shielding layer on a light transmission film that allows transmission of light for exposing the resist layer, and disposing the light transmission film with the light shielding layer thereon on the resist layer.

In an embodiment, a projection lithography stepper is used to expose the predetermined regions of the resist layer one by one.

According to the present invention, a light shielding layer that prevents the resist layer from being exposed is formed on the resist layer, and predetermined regions of the resist layer are exposed one by one. Since the light shielding layer can be formed easily by printing a light shielding material on the resist layer, and thus can be easily removed, plating electrodes can be formed by just forming the light shielding layer on the resist layer according to the shapes and sizes of the plating electrodes, without necessity of preparing various reticle patterns for use of plating electrodes according to shapes and sizes of plating electrodes to be formed. As a result, the shapes and sizes of the plating electrodes do not depend on the reticle patterns, resulting in a greater degree of freedom in formation of the plating electrodes.

For example, when forming a ring-shaped plating electrode, one just needs to form a ring-shaped light shielding layer in the periphery of the resist layer. This enables easy formation of the ring-shaped plating electrode. For example, the ring-shaped plating electrode enables a plating treatment with the current supplied from a peripheral ring.

To the contrary, in the related art, according to the shapes and sizes of the plating electrodes, a number of reticle patterns have to be prepared, and for a portion of the ring, a large number of reticle patterns have to prepared, so that it is not easy to realize formation of a ring-shaped plating electrode.

When forming a number of discrete plating electrodes, one just needs to form a number of discrete light shielding members at the corresponding positions.

These and other objects, features, and advantages of the present invention will become more apparent from the following detailed description of the preferred embodiments given with reference to the accompanying drawings.

### BRIEF DESCRIPTION OF THE DRAWINGS

FIG. 1 is a top view of a semiconductor substrate for illustrating the process of forming plating electrodes in the related art;

FIG. 2 is a cross-sectional view of the semiconductor substrate in FIG. 1 along the line AA′;

FIG. 3 is a top view of the semiconductor substrate for explaining the subsequent process of forming plating electrodes continued from FIG. 1;

FIG. 4 is a cross-sectional view of the semiconductor substrate in FIG. 3 along the line AA′;

FIG. 5 is a top view of the semiconductor substrate for explaining the subsequent process of forming plating electrodes continued from FIG. 3;

FIG. 6 is a top view of the semiconductor substrate for explaining the subsequent process of forming plating electrodes continued from FIG. 5;

FIG. 7 is a top view of a semiconductor substrate for illustrating an example of a method of forming plating electrodes according to an embodiment of the present invention;

FIG. 8 is a cross-sectional view of the semiconductor substrate in FIG. 7 along the line AA′;

FIG. 9 is a top view of the semiconductor substrate for explaining the subsequent process of forming plating electrodes continued from FIG. 7;

FIG. 10 is a cross-sectional view of the semiconductor substrate in FIG. 9 along the line AA′;

FIG. 11 is a top view of the semiconductor substrate for explaining the subsequent process of forming plating electrodes continued from FIG. 9;

FIG. 12 is a cross-sectional view of the semiconductor substrate in FIG. 11 along the line AA′;

FIG. 13 is a top view of the semiconductor substrate for explaining the subsequent process of forming plating electrodes continued from FIG. 11;

FIG. 14 is a top view of the semiconductor substrate for explaining the subsequent process of forming plating electrodes continued from FIG. 13;

FIG. 15 is a cross-sectional view of the semiconductor substrate in FIG. 14 along the line AA′;

FIG. 16 is a top view of a semiconductor substrate for explaining another example of forming plating electrodes; and

FIG. 17 is a top view of the semiconductor substrate for explaining the subsequent process of forming plating electrodes continued from FIG. 16.

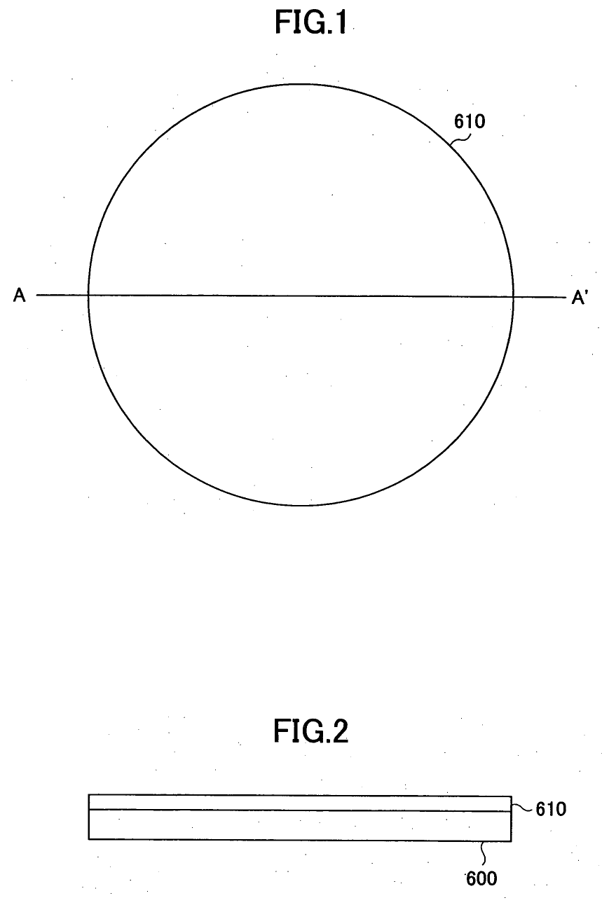

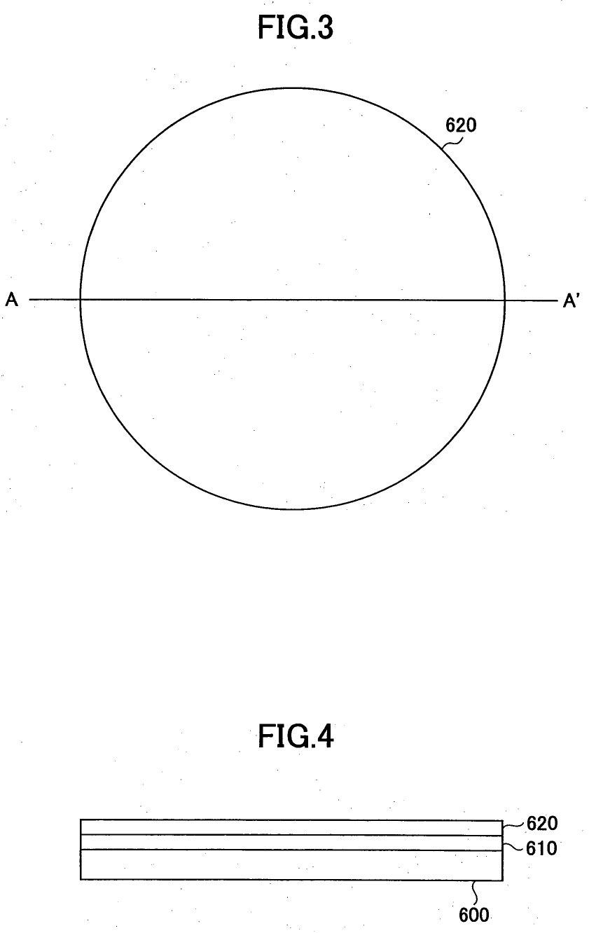

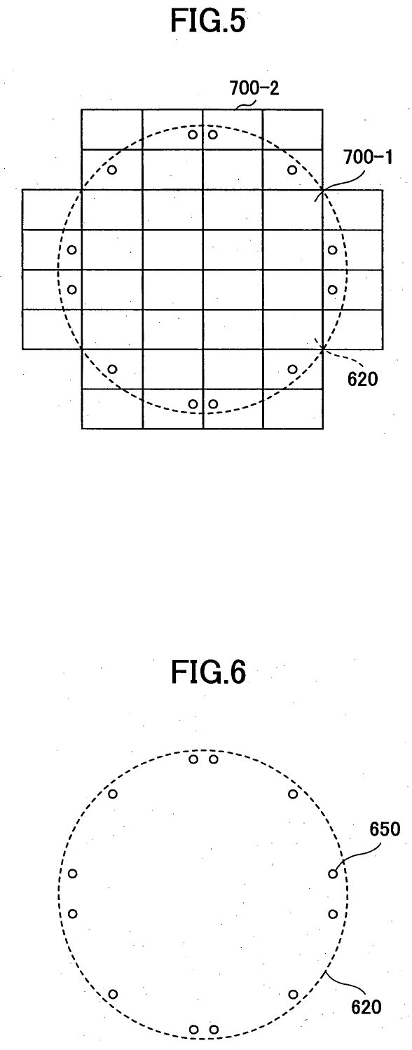

### DESCRIPTION OF THE PREFERRED EMBODIMENTS

Below, preferred embodiments of the present invention are explained with reference to the accompanying drawings.

Specifically, descriptions are made of methods of forming plating electrodes on a semiconductor wafer, for example, in a Super Chip-Size Package (Super CSP) semiconductor product having copper posts or other conductive posts on a surface of a semiconductor chip cut out from the semiconductor wafer, or in a process of forming a semiconductor product having solder bumps or other bumps on the surface of the semiconductor wafer.

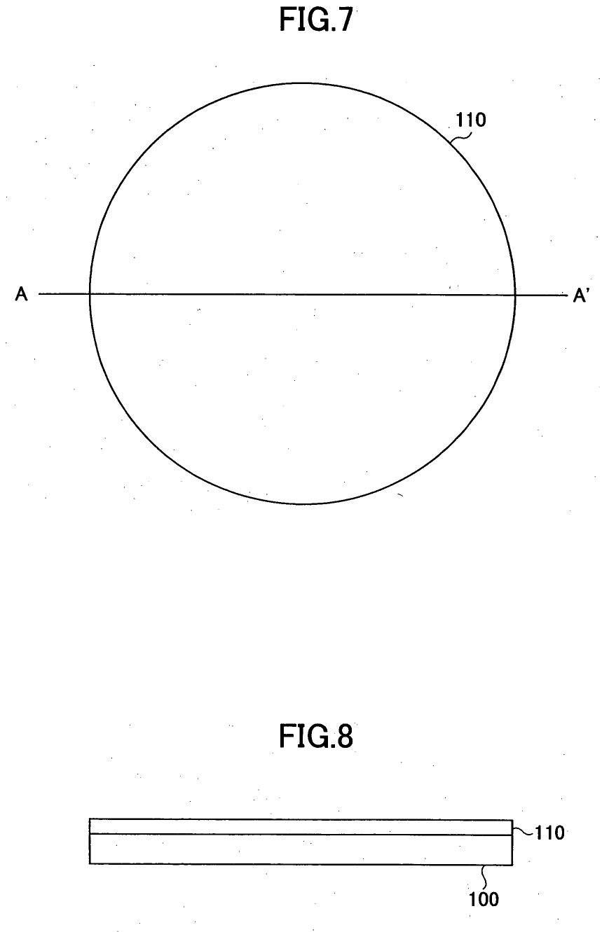

FIG. 7 is a top view of a semiconductor substrate for illustrating an example of a method of forming plating electrodes according to an embodiment of the present invention.

FIG. 8 is a cross-sectional view of the semiconductor substrate in FIG. 7 along the line AA′.

In step 1, as illustrated in FIG. 7 and FIG. 8, a conductive metal layer 110 for forming interconnections is deposited on a semiconductor wafer 100, for example, a silicon wafer having a diameter of 8 inches (20.32 cm). The conductive metal layer 110 may be formed by sputtering, in which ions are sputtered on the surface of the semiconductor wafer 100 acting as a target by using glow discharge in an environment of argon gas or other discharging gases.

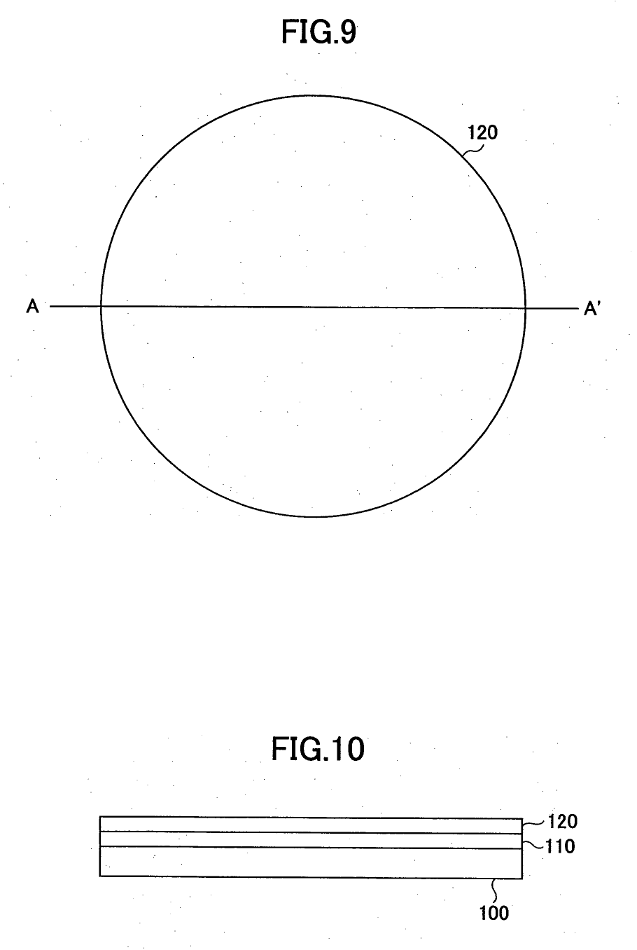

FIG. 9 is a top view of the semiconductor substrate for explaining the subsequent process of forming plating electrodes continued from FIG. 7.

FIG. 10 is a cross-sectional view of the semiconductor substrate in FIG. 9 along the line AA′.

In step 2, as illustrated in FIG. 9 and FIG. 10, a negative resist layer 120 is formed on the conductive metal layer 110. The negative resist layer 120 has a characteristic in that the portion of the negative resist layer 120 irradiated by ultraviolet rays becomes insoluble or hardly soluble in a developing solution, and remains on the surface of the conductive metal layer 110 after the development. The negative resist layer 120 is obtained by pasting a dry film resist (DFR) on the conductive metal layer 110, or coating a photo-sensitive resin resist on the conductive metal layer 110.

It is easy to obtain the negative resist layer 120 by pasting the dry film resist (DFR) on the conductive metal layer 110, and furthermore, the pasted negative resist layer 120 can be easily removed after the plating treatment.

When the negative resist layer 120 is obtained by coating the photo-sensitive resin resist on the conductive metal layer 110, for example, spin-coating is used to perform the coating. In this case, the thickness, material, and viscosity of the negative resist layer 120 are determined by the rotational speed of the spinner.

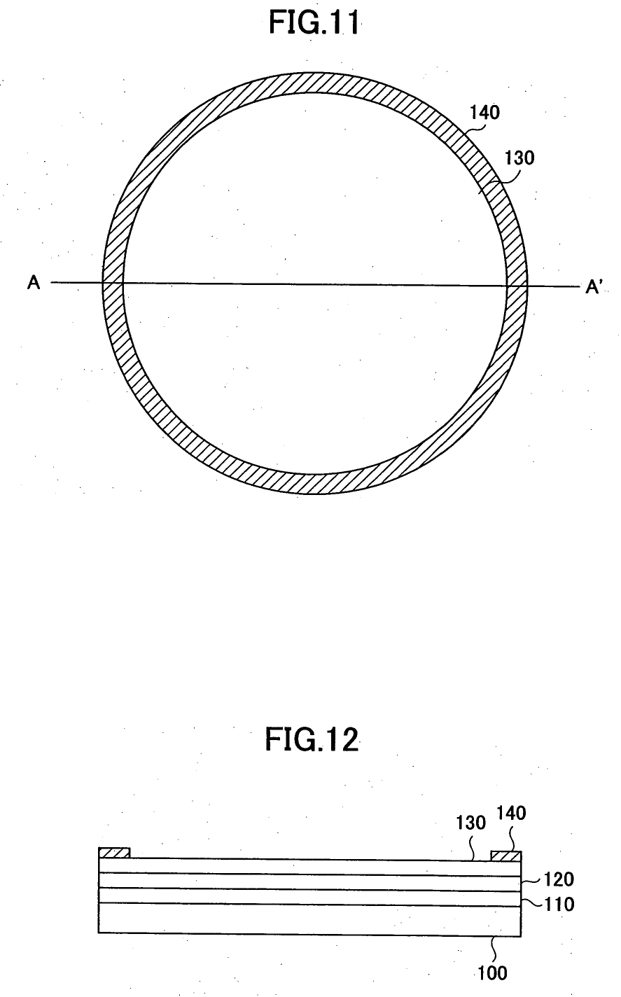

FIG. 11 is a top view of the semiconductor substrate for explaining the subsequent process of forming plating electrodes continued from FIG. 9.

FIG. 12 is a cross-sectional view of the semiconductor substrate in FIG. 11 along the line AA′.

In step 3, as illustrated in FIG. 11 and FIG. 12, a protection film 130, which allows transmission of light for exposure, is applied on the negative resist layer 120 to protect the negative resist layer 120 after step 3 and before subsequent step 5 (described below).

For example, the protection film 130 is formed by PET (Poly Ethylene Terephthalate), and further, ink is printed on the protection film 130, thereby, a ring-shaped light shielding layer 140 is formed in the peripheral region of the negative resist layer 120. The light shielding layer 140 shields light from irradiating onto the underlying negative resist layer 120.

The light shielding layer 140 may be formed by printing ink on the protection film 130, for example, by using a common inkjet printer. In addition to ink, the light shielding layer 140 may also be formed from any materials capable of shielding light. For example, use can be made of an epoxy resin including pigment capable of shielding light, and the epoxy resin can be coated on the protection film 130 by a dispenser.

Further, the light shielding layer 140 may be formed by methods other than that described above. For example, the light shielding layer 140 may be formed beforehand on the protection film 130 in a ring shape corresponding to the edge of the negative resist layer 120, and the protection film 130 partially covered with the light shielding layer 140 is then pasted on the negative resist layer 120.

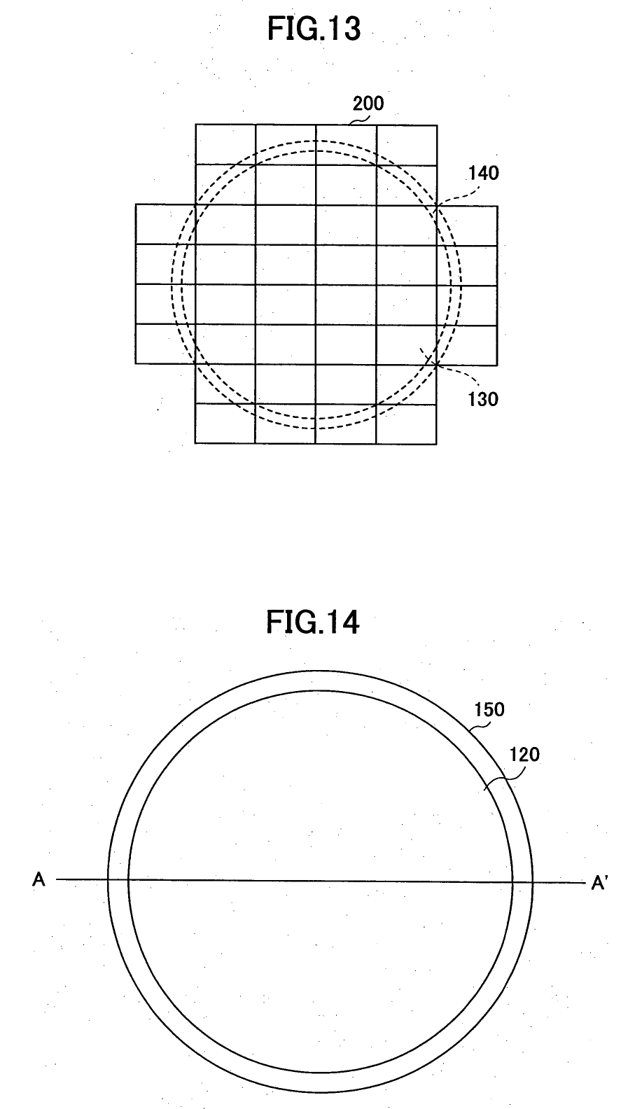

FIG. 13 is a top view of the semiconductor substrate for explaining the subsequent process of forming plating electrodes continued from FIG. 11.

In step 4 as illustrated in FIG. 13, a reticle pattern (not illustrated) is disposed at a specified position above the protection film 130 which is formed on the negative resist layer 120. Further, a projection lithography stepper (not illustrated) is arranged above the reticle pattern. The projection lithography stepper emits ultraviolet rays on the negative resist layer 120 through the reticle pattern, and thereby exposing the negative resist layer 120.

In the grid area shown in FIG. 13, each cell 200 indicates an area exposed by the projection lithography stepper one time (that is, unit exposure area). The projection lithography stepper exposes the cells 200 one by one. In this exposure process, only one type of reticle pattern is used so as to prevent exposure of areas of the negative resist layer 120 where conductive posts are to be formed.

By irradiation of light onto the negative resist layer 120 by the projection lithography stepper, the negative resist layer 120 is exposed except for the portion below the light shielding layer 140, and the portion of the negative resist layer 120 irradiated by the ultraviolet rays becomes insoluble or hardly soluble in the developing solution. But, the portion of the negative resist layer 120 below the light shielding layer 140 is not exposed and remains soluble in the developing solution.

FIG. 14 is a top view of the semiconductor substrate for explaining the subsequent process of forming plating electrodes continued from FIG. 13.

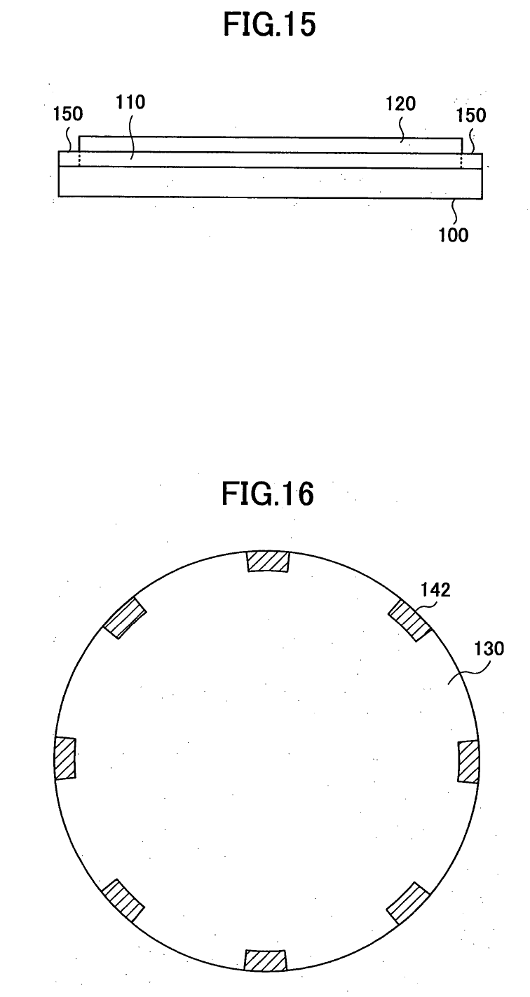

FIG. 15 is a cross-sectional view of the semiconductor substrate in FIG. 14 along the line AA′.

In step 5, the protection film 130, which carries the light shielding layer 140 and is pasted on the negative resist layer 120, is removed. Then, the semiconductor wafer 100 is immersed in the developing solution for the developing treatment.

As illustrated in FIG. 14 and FIG. 15, the exposed portion of the negative resist layer 120, that is, the portion not covered by the light shielding layer 140, becomes insoluble or hardly soluble in the developing solution, and remains on the surface of the conductive metal layer 110 after the development. Meanwhile, the portion of the negative resist layer 120 below the light shielding layer 140 is not exposed and remains soluble in the developing solution; therefore, this portion of the negative resist layer 120 is removed after the development. As a result, the conductive metal layer 110 previously covered by the removed negative resist layer 120 is exposed in a ring shape. This ring portion of the conductive metal layer 110 is used as the plating electrode 150.

Subsequently, a plating treatment is performed by supplying a current to the ring-shaped plating electrode 150, thereby, conductive posts and bumps are formed on the conductive metal layer 110.

After the plating treatment, the whole negative resist layer 120 is removed.

In the exposure process, only one type of reticle pattern is used to prevent exposure of areas of the negative resist layer 120 where conductive posts are to be formed. As described above, the light shielding layer 140 can be easily formed by printing ink on the protection film 130 and other well known methods, and the light shielding layer 140 can also be easily removed. Therefore, when forming the plating electrodes, it is not necessary to prepare reticle patterns in advance for use of plating electrodes according to shapes and sizes of the plating electrodes, but just printing the light shielding layer in desired shapes and sizes. Furthermore, when it is required to change shapes and sizes of the plating electrodes, it is sufficient to remove the previously formed light shielding layer and print a new light shielding layer. As a result, the shapes and sizes of the plating electrodes are not limited by the reticle patterns, resulting in a greater degree of freedom in formation of the plating electrodes.

In the above description, a ring-shaped plating electrode 150 is formed by exposing the whole outer edge portion of the conductive metal layer 110. Alternatively, a number of discrete plating electrodes can also be obtained by exposing selected portions of the conductive metal layer 110.

For this purpose, for example, instead of the step illustrated in FIG. 11 and FIG. 12, the step shown in FIG. 16 is executed.

FIG. 16 is a top view of a semiconductor substrate for explaining another example of forming plating electrodes.

Specifically, the protection film 130, which allows transmission of light for exposure, is applied on the negative resist layer 120 to protect the negative resist layer 120 in the subsequent processes. Further, a number of light shielding members 142 are formed along the outer edge of the negative resist layer 120. For example, light shielding members 142 are from the same material as the light shielding layer 140.

Preferably, the light shielding members 142 are arranged on the negative resist layer 120 in such a way that one of the light shielding members 142 faces another one of the light shielding members 142, and thus the plating electrodes are correspondingly formed on the semiconductor wafer 100 in this way, that is, one of the plating electrodes faces another one of the plating electrodes on the semiconductor wafer 100. Consequently, the thus formed conductive posts and bumps are uniformly arranged on the conductive metal layer 110.

Alternatively, the light shielding members 142 may be formed in the following way, that is, the light shielding members 142 are formed beforehand on the protection film 130 at positions corresponding to the edge of the negative resist layer 120, and the protection film 130 partially covered with the light shielding members 142 is then pasted on the negative resist layer 120.

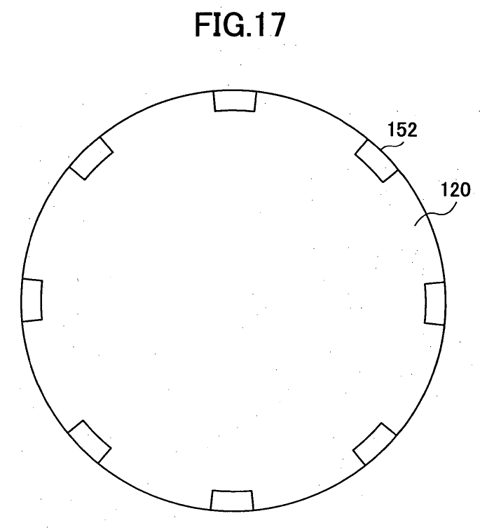

FIG. 17 is a top view of the semiconductor substrate for explaining the process of forming plating electrodes subsequent to FIG. 16.

In FIG. 17, the protection film 130, which is partially covered by the light shielding members 142 and is pasted on the negative resist layer 120, is removed, and further, the semiconductor wafer 100 is immersed in a developing solution for developing. As a result, the portions of the negative resist layer 120 previously below the light shielding members 142 are removed after the development. Therefore, the portions of the conductive metal layer 110 originally covered by the removed negative resist layer 120 are exposed, and these conductive metal pieces are used as the plating electrodes 152.

Subsequently, plating treatment is performed with the plating current supplied from the plating electrodes 152, and thereby, conductive posts and bumps are formed on the conductive metal layer 110.

In the present embodiment, the protection film 130 is formed on the negative resist layer 120, and the light shielding layer 140 is formed on the protection film 130 in a ring shape corresponding to the edge of the negative resist layer 120, or a number of the light shielding members 142 are formed on the protection film 130 at positions corresponding to the edge of the negative resist layer 120. Then, with a projection lithography stepper, and by using only one type of reticle pattern (for formation of conductive posts), specified regions of the negative resist layer 120 are exposed one by one.

Subsequently, the protection film 130 is removed, developing treatment is performed, and thus the portions of the negative resist layer 120 previously below the light shielding layer 140 or the light shielding members 142 are removed; the portions of the conductive metal layer 110 originally covered by the removed negative resist layer 120 are exposed, and these conductive metal pieces are used as the plating electrodes 150 or 152.

Therefore, it is not necessary to prepare a lot of reticle patterns according to shapes and sizes of the plating electrodes 150 and 152 as is done in the related art, and it is possible to form the plating electrodes 150 and 152 by just forming the light shielding layer 140 and the light shielding members 142, respectively, on the negative resist layer 120 according to the shapes and sizes of the plating electrodes 150 and 152. As a result, the shapes and sizes of the plating electrodes 150 and 152 do not depend on the reticle pattern, and can be formed with a greater degree of freedom.

In addition, because it is not necessary to prepare various kinds of reticle patterns, and it is sufficient to just form the light shielding layer 140 and the light shielding members 142 on the negative resist layer 120, the fabrication cost can be reduced.

When a projection lithography stepper is used to expose the negative resist layer 120 to form a ring-shaped plating electrode, in the related art, because it is necessary to prepare a lot of reticle patterns for a portion of the ring, it is not easy to realize formation of a ring-shaped plating electrode.

In contrast, in the present embodiment, the ring-shaped light shielding layer 140 is formed along the outer edge of the negative resist layer 120, and this makes formation of the ring-shaped plating electrode easy. For example, the ring-shaped plating electrode enables plating treatment with the current supplied from a peripheral ring.

While the present invention has been described with reference to specific embodiments chosen for purpose of illustration, it should be apparent that the invention is not limited to these embodiments, but numerous modifications could be made thereto by those skilled in the art without departing from the basic concept and scope of the invention.

Summarizing the effect of the invention, according to the present invention, it is possible to form a plating electrode with a large degree of freedom in shape and position of the plating electrode.

This patent application is based on Japanese Priority Patent Application No. 2003-166818 filed on Jun. 11, 2003, the entire contents of which are hereby incorporated by reference.

What is claimed is:

1. A method of forming a plating electrode, the method comprising the steps of:
forming a conductive metal layer on a semiconductor wafer;
forming a resist layer on the conductive metal layer;
forming a light shielding layer on the resist layer to cover a predetermined portion of the resist layer so as to prevent the predetermined portion of the resist layer from being exposed;
exposing a region of the resist layer not covered by the light shielding layer each time one unit region;
removing the light shielding layer; and
removing the predetermined portion of the resist layer previously being covered by the light shielding layer to expose a corresponding portion of the conductive metal layer, said exposed portion of the conductive metal layer being used as the plating electrode.

2. The method as claimed in claim 1, wherein:
in the step of forming the light shielding layer, the light shielding layer is formed by printing a light shielding material on the resist layer.

3. The method as claimed in claim 1, wherein:
in the step of forming the light shielding layer, the light shielding layer is formed to cover a peripheral region of the resist layer.

4. The method as claimed in claim 3, wherein:
the light shielding layer has a ring shape.

5. The method as claimed in claim 1, wherein:
in the step of forming the light shielding layer, the light shielding layer comprises a plurality of light shielding members.

6. The method as claimed in claim 5, wherein:
each of the light shielding members is arranged to face another one of the light shielding members.

7. The method as claimed in claim 1, wherein:
the step of forming the light shielding layer comprises the steps of:
forming the light shielding layer on a light transmission film that allows transmission of light for exposing the resist layer; and
disposing the light transmission film with the light shielding layer thereon on the resist layer.

8. The method as claimed in claim 1, wherein:
in the step of exposing, a projection lithography stepper is used to expose the uncovered region of the resist layer each time one unit region.
